(19) United States
(12) Patent Application Publication
(10) Pub. No.: US 2025/0311541 A1
(43) Pub. Date: Oct. 2, 2025

(54) ORGANIC LIGHT-EMITTING ELEMENT

(71) Applicant: CANON KABUSHIKI KAISHA, Tokyo (JP)

(72) Inventors: HIROAKI SANO, Tokyo (JP); YOJIRO MATSUDA, Kanagawa (JP); TAKAYUKI ITO, Kanagawa (JP)

(21) Appl. No.: 19/236,368

(22) Filed: Jun. 12, 2025

Related U.S. Application Data
(63) Continuation of application No. PCT/JP2023/038060, filed on Oct. 20, 2023.

(30) Foreign Application Priority Data
Dec. 13, 2022 (JP) 2022-198815

(51) Int. Cl. H10K 50/19; H10K 50/856; H10K 50/858; H10K 59/12; H10K 59/90

(52) U.S. Cl. CPC H10K 50/19; H10K 50/856; H10K 50/858; H10K 59/12; H10K 59/90

(57) ABSTRACT

An organic light-emitting element includes a first element having, on a substrate, a first lower electrode, a first light-emitting layer, a charge generation layer, a second light-emitting layer, and an upper electrode in this order, and an insulating layer covering an end of the first lower electrode, wherein the first element has one or more organic layers between the first lower electrode and the charge generation layer, and has one or more organic layers between the charge generation layer and the upper electrode, the insulating layer has a groove on a surface that is in contact with the organic layer disposed between the first lower electrode and the charge generation layer, and at least one of the organic layers disposed between the charge generation layer and the upper electrode is formed in the groove.

### CROSS-REFERENCE TO RELATED APPLICATIONS

This application is a Continuation of International Patent Application No. PCT/JP2023/038060, filed Oct. 20, 2023, which claims the benefit of Japanese Patent Application No. 2022-198815, filed Dec. 13, 2022, both of which are hereby incorporated by reference herein in their entirety.

### BACKGROUND

### Field of the Technology

The technology of the present disclosure relates to an organic light-emitting element.

### Description of the Related Art

An organic light-emitting element (also referred to as an organic electroluminescence element (organic EL device)) is an electronic element having a pair of electrodes and an organic compound layer disposed between these electrodes. By injecting electrons and holes from the pair of electrodes, excitons of the luminescent organic compound in the organic compound layer are generated, and the organic light-emitting element emits light when the excitons return to the ground state. Recent progress of organic light-emitting elements has been remarkable with low driving voltage, various emission wavelengths, high speed responsiveness, and reduction in thickness and weight of light-emitting devices being promoted.

For the organic light-emitting element, there is known a method of depositing an organic layer for each color by using a metal mask, photolithography, or the like (hereinafter referred to as a differently coating method) in order to improve the efficiency.

On the other hand, in order to improve the power consumption of the organic light-emitting elements, tandem type organic light-emitting elements are known in which a charge generation layer is provided between a plurality of light-emitting layers. By applying an electric field between the lower electrode and the upper electrode, carriers are generated in the charge generation layer, and carriers are supplied to each light-emitting unit. For this reason, the light-emitting layer included in each light-emitting unit can be caused to efficiently emit light.

PTL 1 describes an organic light-emitting element having a light-emitting layer deposited thereon by a differently coating method. PTL 1 describes an organic light-emitting element having a first light-emitting unit and a second light-emitting unit between a first electrode and a second electrode, and having a charge generation layer between the light-emitting units. Further, in PTL 1, the thickness of the layer between the light-emitting layer of the first light-emitting unit and the light-emitting layer of the second light-emitting unit is set larger than the thickness between the first light-emitting layer and the first electrode, which can increase the light-emitting efficiency by the microcavity effect.

In the organic light-emitting element of PTL 1, a charge generation layer is provided between a plurality of light-emitting layers. When the charge generation layer is configured to be shared by a plurality of pixels, charges supplied from the charge generation layer may be supplied to adjacent pixels to generate a leakage current. In order to reduce such a leakage current between pixels, PTL 2 proposes a technique of forming a groove between sub-pixels. Since the thickness of the organic compound layer in the inside of the groove is smaller than the thickness of the organic compound layer outside the groove, the resistance of the inside of the groove is increased. As a result, a leakage current between adjacent sub-pixels is suppressed, and color mixture of emission colors of adjacent sub-pixels is suppressed.

However, the organic light-emitting element of PTL 1 is configured such that the organic film may become thick, for example, the thickness between the light-emitting layer of the first light-emitting unit and the light-emitting layer of the second light-emitting unit is increased due to the microcavity effect. Therefore, since the inside of the groove is filled with the organic film before the formation of the charge generation layer, the charge generation layer is not formed in the inside of the groove, and charges supplied from the charge generation layer may be supplied to the pixels.

### CITATION LIST

### Patent Literature

PTL 1 U.S. Patent Application Publication No. 2015/0188087
PTL 2 Japanese Patent Application Publication No. 2012-216338

### SUMMARY

The technique of the present disclosure has been made in view of the above-described problems, and provides a technique of suppressing a leakage current between a charge generation layer and an upper electrode in a pixel while enhancing light emission efficiency by a microcavity effect in an organic light-emitting element.

According to some embodiments, an organic light-emitting element includes a first element having, on a substrate, a first lower electrode, a first light-emitting layer that emits light of a first color, a charge generation layer, a second light-emitting layer that emits light of the first color, and an upper electrode in this order, and an insulating layer covering an end of the first lower electrode, wherein the first element has one or more organic layers between the first lower electrode and the charge generation layer, and has one or more organic layers between the charge generation layer and the upper electrode, the insulating layer has a groove on a surface that is in contact with the organic layer disposed between the first lower electrode and the charge generation layer, and at least one of the organic layers disposed between the charge generation layer and the upper electrode is formed in the groove.

According to some embodiments, a display device includes a plurality of pixels, wherein at least one of the plurality of pixels includes the organic light-emitting element as described above, and a transistor connected to the organic light-emitting element. According to some embodiments, a photoelectric conversion device includes an optical unit having a plurality of lenses, an imaging element that receives light that has passed through the optical unit, and a display unit that displays an image captured by the imaging element, wherein the display unit includes the organic light-emitting element as described above. According to some embodiments, an electronic device includes a display unit having the organic light-emitting element as described above, a housing provided with the display unit, and a communication unit provided in the housing and that communicates with the outside. According to some embodiments, a lighting device includes a light source having the organic light-emitting element as described above, and a light diffusion part or an optical film that transmits light emitted by the light source therethrough. According to some embodiments, a moving body includes a lamp having the organic light-emitting element as described above, and a body provided with the lamp.

Features of the present disclosure will become apparent from the following description of embodiments with reference to the attached drawings. The following description of embodiments are described by way of example.

### BRIEF DESCRIPTION OF THE DRAWINGS

FIG. 1 is a cross sectional view illustrating an example of a light-emitting element according to an embodiment of the present disclosure.

FIG. 2 is a cross sectional view illustrating an example of the light-emitting element according to an embodiment of the present disclosure.

FIG. 3 is a cross sectional view illustrating an example of the light-emitting element according to an embodiment of the present disclosure.

FIG. 4 is a cross sectional view illustrating an example of the light-emitting element according to an embodiment of the present disclosure.

FIG. 5 is a cross sectional view illustrating an example of the light-emitting element according to an embodiment of the present disclosure.

FIG. 6 is a cross sectional view illustrating an example of the light-emitting element according to an embodiment of the present disclosure.

FIG. 7 is a cross sectional view of a light-emitting element according to a comparative example.

FIG. 8 is a plan view of a light-emitting element according to a comparative example.

FIGS. 9A and 9B are each a cross sectional view illustrating an example of a display device according to an embodiment of the present disclosure.

FIG. 10 is a view illustrating an example of a display device according to an embodiment of the present disclosure.

FIGS. 11A and 11B are views showing an example of an imaging device and an electronic apparatus according to an embodiment.

FIGS. 12A and 12B are views illustrating an example of a display device according to an embodiment.

FIGS. 13A and 13B are views showing an example of an automobile having a lighting device and a lamp according to an embodiment.

FIGS. 14A and 14B are views showing an example of a wearable device according to an embodiment.

### DESCRIPTION OF THE EMBODIMENTS

The following is a description of the embodiments of the present disclosure with reference to the drawings. Note that the present disclosure is not limited to the following embodiments, and may be changed as appropriate within the scope not departing from the gist thereof. Further, in the drawings described below, those having the same function are given the same reference numerals and signs, and description thereof may be omitted or simplified.

### First Embodiment

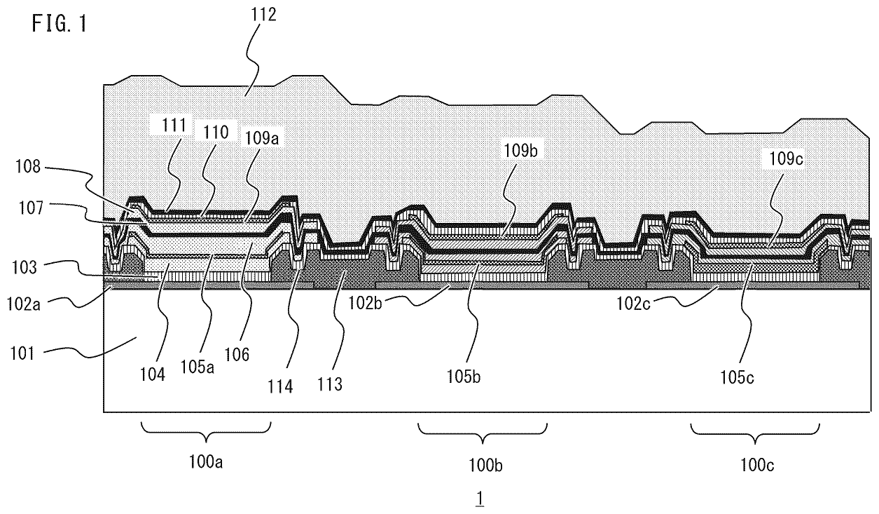

A light-emitting element for use in a first embodiment will be described. FIG. 1 is a cross sectional view showing an example of a first sub-pixel 100a, a second sub-pixel 100b, and a third sub-pixel 100c of a light-emitting element 1 according to the present embodiment.

The light-emitting element 1 of FIG. 1 includes, on a substrate 101, lower electrodes 102a to 102c, a first organic layer 103, a second organic layer 104, first light-emitting layers 105a to 105c, and a third organic layer 106 in this order. Further, the light-emitting element 1 includes, on the third organic layer 106, a charge generation layer 107, a fourth organic layer 108, second light-emitting layers 109a to 109c, a fifth organic layer 110, an upper electrode 111, and a protective layer 112 in this order. Further, as shown in the drawing, an insulating layer 113 is provided covering both ends of the lower electrode 102a, and the insulating layer 113 is also called a pixel isolation film or a bank. Similarly, an insulating layer covering both ends of the lower electrodes 102b and 102c is provided.

A groove 114 is formed in the insulating layer 113 as an isolation structure. Here, the first sub-pixel 100a is an example of a first element, and the lower electrode 102a corresponds to the first lower electrode, the first light-emitting layer 105a corresponds to the first light-emitting layer emitting light of a first color, and the second light-emitting layer 109a corresponds to the second light-emitting layer emitting light of the first color. Further, the second sub-pixel 100b is an example of a second element, and the lower electrode 102b corresponds to the second lower electrode, the first light-emitting layer 105b corresponds to the third light-emitting layer emitting light of a second color, and the second light-emitting layer 109b corresponds to the fourth light-emitting layer emitting light of the second color.

In the light-emitting element 1 of the present embodiment, the first light-emitting layers 105a to 105c and the second light-emitting layer 109 are deposited by a so-called differently coating method. That is, an organic layer is deposited for each color by using, for example, a metal mask or photolithography. As a result, the first light-emitting layers 105a to 105c emit light of different colors. Further, second light-emitting layers 109a to 109c also emits light of different colors. Also, in the present embodiment, at least one layer of the first organic layer 103, the second organic layer 104, the third organic layer 106, the fourth organic layer 108, and the fifth organic layer 110 is deposited by a differently coating method.

The light-emitting element 1 of the present embodiment is a so-called tandem type light-emitting element in which a charge generation layer is provided between a plurality of light-emitting layers, and has a charge generation layer 107. The charge generation layer 107 is a layer that generates holes and electrons by being applied with a voltage between the lower electrode and the upper electrode. The charge generation layer 107 contains a compound that tends to accept electrons from other organic compounds. For example, the charge generation layer 107 is formed of a combination of an alkali metal and a compound having a lowest unoccupied molecular orbital energy of −5.0 eV or less, and can function as a charge generation layer. The alkali metal constituting the charge generation layer 107 may be Li, and Li may be used as a metal simple substance, a part of a compound, or a part of an organometallic complex.

Further, the compound having a lowest unoccupied molecular energy of −5.0 eV or less used for the charge generation layer 107 may be a hexaazatriphenylene compound, a radialene compound, hexafluoroquinodimethane or the like, but is not limited to these. The lowest unoccupied molecular energy is low enough to pull electrons out of the highest occupied molecular orbital (HOMO; Highest Occupied Molecular Orbital) of the alkali metal, so that charge generation can be performed.

As a result, positive and negative charges are generated in the charge generation layer 107, so that the charge generation layer 107 can supply positive or negative charges to the upper layer and the lower layer of the charge generation layer 107. That is, by applying an electric field between the lower electrode and the upper electrode, carriers are generated in the charge generation layer 107, and carriers are supplied to the first light-emitting layers 105a to 105c and the second light-emitting layers 109a to 109c, so that both the light-emitting layers can efficiently emit light.

The light-emitting element 1 of the present embodiment is configured such that the groups of the first light-emitting layers 105a to 105c and the second light-emitting layers 109a to 109c emit light of the same color, respectively, by adopting a differently coating method. For example, it may be configured such that the group of the first light-emitting layer 105a and the second light-emitting layer 109a emits red light, the group of the first light-emitting layer 105b and the second light-emitting layer 109b emits green light, and the group of the first emitting layer 105c and the second light-emitting layer 109c emits blue light.

Furthermore, the light-emitting element 1 of the present embodiment also has a so-called microcavity structure. That is, when the optical path length from the upper surfaces of the lower electrodes 102a to 102c to the light-emitting positions of the first light-emitting layers 105a to 105c corresponding to the lower electrodes 102a to 102c is assumed to be Lr and the phase shift in the lower electrode 102 is assumed to be Φr, the following expression (1) holds.

Lr=(2m−(Φr/π))×(λ/4) (1)

Here, m is an integer of 0 or more. Each optical distance of the first organic layer 103 and the second organic layer 104 can be optimized for each color so as to satisfy the above expression (1).

Further, the optical distance Ls between the light-emitting position and the reflecting surface of the upper electrode 111 satisfies the following equation (2), where Φs represents a phase shift when light having a wavelength λ is reflected on the incident surface. It should be noted that m′ is an integer of 0 or more, and m′ is equal to 0 in the present embodiment.

Ls=(2m′−Φ(s/π))×(λ/4)=−(Φs/π)×(λ/4) (2)

Accordingly, for the all-layer interference L, the conditions shown in the following equation (3) are satisfied.

L=Lr+L=(2m−Φ/π)×(λ/4) (3)

Here, Φ is the sum of phase shifts Φr+Φs when light with a wavelength of Φ is reflected by the lower electrode 102 and the upper electrode 111.

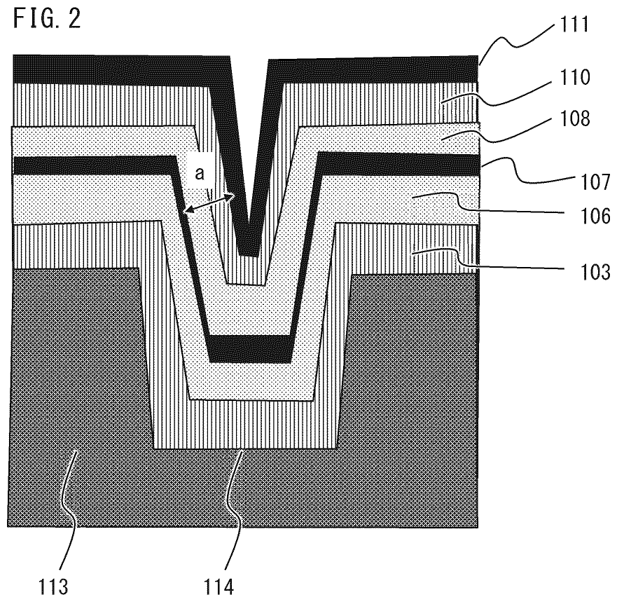

Although the case of the first light-emitting layers 105a to 105c have been shown above, the above relationship also similarly holds for the second light-emitting layers 109a to 109c. Accordingly, since the first light-emitting layers 105a to 105c and the second light-emitting layers 109a to 109c are both configured as a microcavity structure, the light-emitting element 1 can achieve more highly efficient light emission than a light-emitting element by the prior art.

[Suppression of Leakage Current Between the Charge Generation Layer and the Upper Electrode] FIG. 2 is an enlarged cross sectional view of the vicinity of the groove 114 in FIG. 1. The groove 114 is disposed in the insulating layer 113, and a first organic layer 103, a third organic layer 106, a charge generation layer 107, a fourth organic layer 108, a fifth organic layer 110, and an upper electrode 111 are disposed in the inside of the groove 114. In the present embodiment, the fourth organic layer 108 and the fifth organic layer 110 are formed in the inside of the groove 114, thereby suppressing thinning of the thickness (“a” in the drawing) of the organic film from the charge generation layer 107 to the upper electrode 111 at the sidewall portion in the inside of the groove 114. Since the organic film from the charge generation layer 107 to the upper electrode 111 on the sidewall portion in the inside of the groove 114 is suppressed from becoming thin, the leakage current between the charge generation layer 107 and the upper electrode 111 is suppressed.

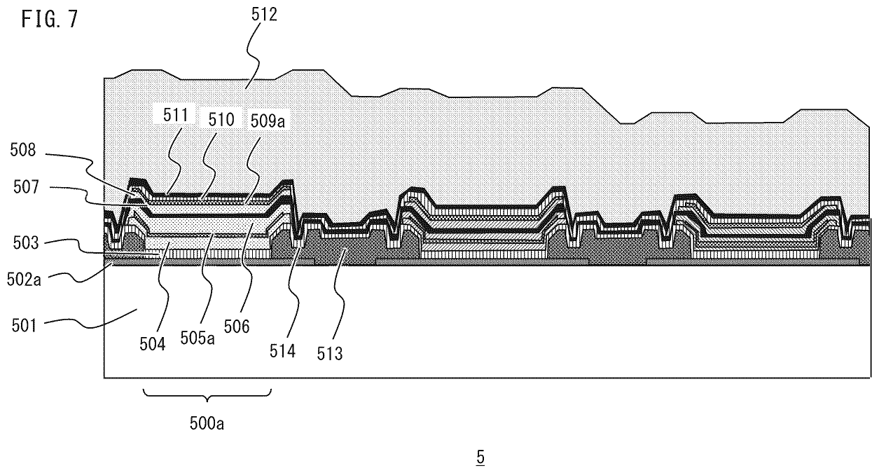

FIG. 7 is a cross sectional view of an organic light-emitting element 5 of the prior art as a comparative example of the light-emitting element 1 of the present embodiment. As shown in FIG. 7, in the light-emitting element 5, a lower electrode 502, a first organic layer 503, a second organic layer 504, a first light-emitting layer 505a, a third organic layer 506, a charge generation layer 507, and a fourth organic layer 508 are formed in this order from the substrate 501 side on the substrate 501. Further, in the light-emitting element 5, on the fourth organic layer 508, a second light-emitting layer 509a, a fifth organic layer 510, an upper electrode 511, and a protective layer 512 are formed in this order from the substrate 501 side. Further, in the light-emitting element 5, an insulating layer 513 covering the end of the lower electrode 502 is provided, and a groove 514 is formed in the insulating layer 513.

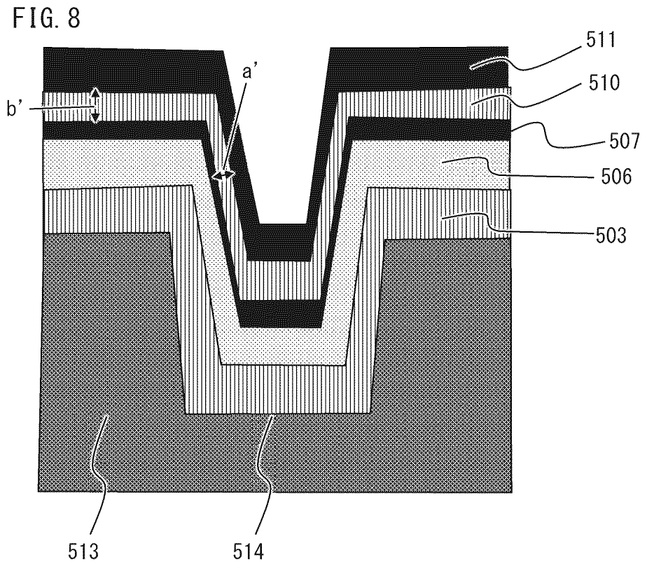

Further, FIG. 8 is an enlarged cross sectional view of the vicinity of the groove 514 in FIG. 7. As shown in FIG. 8, only the fifth organic layer 510 is formed between the charge generation layer 507 and the upper electrode 511. The thickness of the fifth organic layer 510 at the sidewall portion in the inside of the groove 514 (“a′” in the drawing) is smaller than the thickness of the fifth organic layer 510 at the flat portion outside the groove 514 (“b′” in the drawing). As a result, the leakage current between the charge generation layer 507 and the upper electrode 511 at the sidewall portion in the inside of the groove 514 increases. When the leakage current between the charge generation layer 507 and the upper electrode 511 is large, it becomes impossible to supply charges to the light-emitting layer at the time of a low current, so that the luminance may decrease.

On the other hand, in the light-emitting element 1 of the present embodiment, at least one layer of the fourth organic layer 108 and the second light-emitting layer 109 present between the charge generation layer 107 and the upper electrode 111 is deposited in the inside of the groove 114 by a differently coating method. As a result, the thickness of the organic film from the charge generation layer 107 to the upper electrode 111 on the sidewall portion in the inside of the groove 114 is increased, and the leakage current is suppressed.

Further, the thickest layer of the organic layer or the light-emitting layer formed between the charge generation layer 107 and the upper electrode 111 by a differently coating method may be formed in the groove 114. Since the thickest layer is formed in the groove 114, the organic layer formed between the charge generation layer 107 and the upper electrode 111 becomes thicker at the sidewall portion in the inside of the groove 114. This more suppresses a leakage current generated between the charge generation layer 107 and the upper electrode 111.

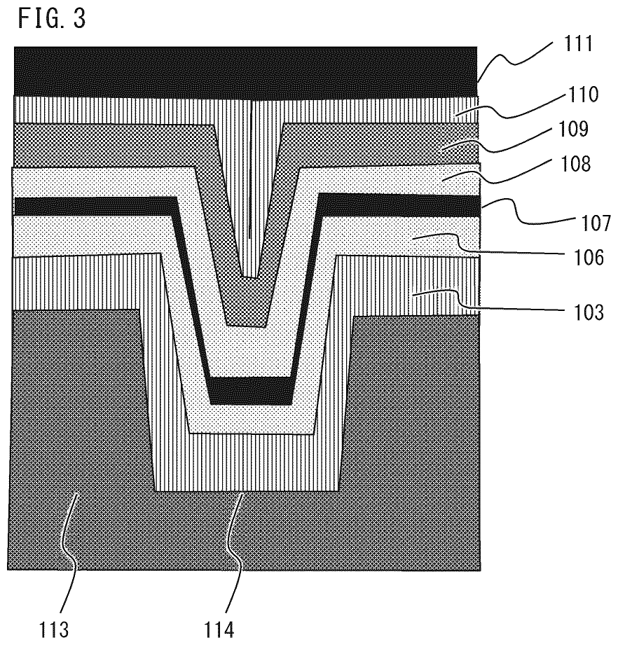

Further, as shown in FIG. 3, the fourth organic layer 108, the second light-emitting layer 109, and the fifth organic layer 110 may be formed in the inside of the groove 114. As shown in FIG. 2, the thickness of the organic layer from the charge generation layer 107 to the upper electrode 111 at the inner sidewall portion of the groove 114 is further increased, so that the leakage current between the charge generation layer 107 and the upper electrode 111 can be suppressed.

Further, after the deposition of the fifth organic layer 110, the groove 114 is filled with the organic layer, and the upper electrode 111 is deposited flat above the groove 114. Since the upper electrode 111 is flattened, the resistance of the upper electrode 111 is reduced, and the driving voltage of the light-emitting element 1 can be reduced.

### Second Embodiment

Next, a light-emitting element according to a second embodiment will be described. Incidentally, in the following description, the same configurations as those of the first embodiment are given the same reference numerals and signs, and detailed description thereof will be omitted.

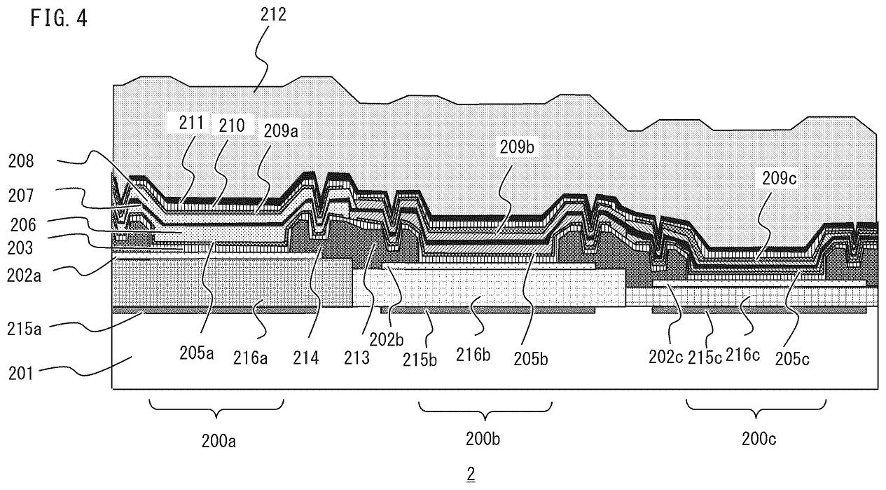

FIG. 4 is a cross sectional view showing an example of the first sub-pixel 200a, the second sub-pixel 200b, and the third sub-pixel 200c of the light-emitting element 2 according to the present embodiment. As shown in the drawing, the light-emitting element 2, as with the light-emitting element 1, has a substrate 201, lower electrodes 202a to 202c, a first organic layer 203, and first light-emitting layers 205a to 205c. Further, the light-emitting element 2 has a third organic layer 206, a charge generation layer 207, a fourth organic layer 208, second light-emitting layers 209a to 209c, a fifth organic layer 210, an upper electrode 211, a protective layer 212, and an insulating layer 213 as with the light-emitting element 1.

In the light-emitting element 2 of the present embodiment, reflection layers 215a to 215c and optical adjustment layers 216a to 216c are further formed with respect to the light-emitting element 1 of the first embodiment. Further, in the light-emitting element 2, a groove 214 is formed in the insulating layer 213 as an isolation structure. The optical adjustment layers 216a to 216c can be composed of an insulating layer. Further, the lower electrodes 202a to 202c can be composed of transparent electrodes. Incidentally, the optical adjustment layer 216a is an example of the first optical adjustment layer, and the optical adjustment layer 216b is an example of the second optical adjustment layer.

In the light-emitting element 2 of the present embodiment, a microcavity structure may be adopted to make the thicknesses of the optical adjustment layers 216a to 216c different for each sub-pixel. For example, it is possible that the thickness of the optical adjustment layer 216a is set so as to satisfy the red interference condition, the thickness of the optical adjustment layer 216b is set so as to satisfy the green interference condition, and the thickness of the optical adjustment layer 216c is set so as to satisfy the blue interference condition.

Further, an optical path length from the upper surface of the reflection layer 215a to the light-emitting position of the first light-emitting layer 205a is assumed to be L1a. The optical path length L1a is the sum of the optical distance between the upper surface of the lower electrode 202a and the first light-emitting layer 205a, the optical distance of the thickness of the lower electrode 202a, and the optical distance of the thickness of the optical adjustment layer 216a. Further, an optical path length from the upper surface of the reflection layer 215b to the light-emitting position of the first light-emitting layer 205b is assumed to be L1b. The optical path length L1b is the sum of the optical distance between the upper surface of the lower electrode 202b and the first light-emitting layer 205b, the optical distance of the thickness of the lower electrode 202b, and the optical distance of the thickness of the optical adjustment layer 216b. Further, an optical path length from the upper surface of the reflection layer 215c to the light-emitting position of the first light-emitting layer 205c is assumed to be L1c. The optical path length L1c is the sum of the optical distance between the upper surface of the lower electrode 202c and the first light-emitting layer 205c, the optical distance of the thickness of the lower electrode 202c, and the optical distance of the thickness of the optical adjustment layer 216c.

Similarly, the optical path length from the upper surface of the reflection layer 215a to the light-emitting position of the second light-emitting layer 209a is assumed to be L2a. The optical path length L2a is the sum of the optical distance between the upper surface of the lower electrode 202a and the second light-emitting layer 209a, the optical distance of the thickness of the lower electrode 202a, and the thickness of the optical adjustment layer 216a. Further, an optical path length from the upper surface of the reflection layer 215b to the light-emitting position of the second light-emitting layer 209b is assumed to be L2b. The optical path length L2b is the sum of the optical distance between the upper surface of the lower electrode 202b and the second light-emitting layer 209b, the optical distance of the thickness of the lower electrode 202b, and the thickness of the optical adjustment layer 216b. Further, an optical path length from the upper surface of the reflection layer 215c to the light-emitting position of the second light-emitting layer 209c is assumed to be L2c. The optical path length L2c is the sum of the optical distance between the upper surface of the lower electrode 202c and the second light-emitting layer 209c, the optical distance of the thickness of the lower electrode 202c, and the thickness of the optical adjustment layer 216c.

Thus, in the light-emitting element 2 of the present embodiment, an optical resonator structure is provided between the reflection layer 215a and the first light-emitting layer 205a, which causes the light emitted from the first light-emitting layer 205a to be reflected by the reflection layer 215a for resonance. Further, an optical resonator structure is provided between the reflection layer 215b and the first light-emitting layer 205b which causes the light emitted from the first light-emitting layer 205b to be reflected by the reflection layer 215b for resonance. Furthermore, an optical resonator structure for resonating light emitted from the first light-emitting layer 205c is provided between the reflection layer 215c and the first light-emitting layer 205c. In the light-emitting element 2 of the present embodiment, the total film thickness of the organic layer is reduced by the optical distance of the respective thicknesses of the lower electrodes 202a to 202c and the optical adjustment layers 216a to 216c corresponding to the lower electrodes 202a to 202c. As the total film thickness of the organic layer decreases, the voltage applied to the organic light-emitting element decreases. Then, the total film thickness of the organic layer is reduced by the optical distance of the respective thicknesses of the lower electrodes 202a to 202c and the optical adjustment layers 216a to 216c corresponding to the lower electrodes 202a to 202c, and the driving voltage is suppressed, resulting in the reduction of the power consumption.

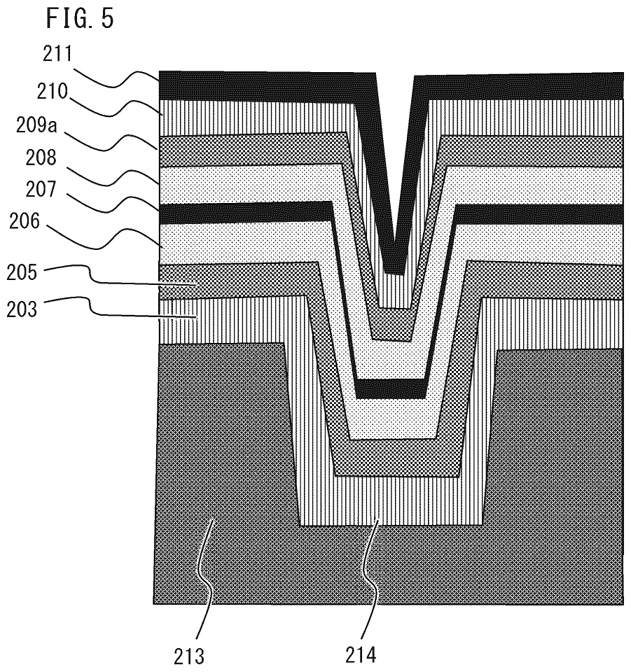

Further, FIG. 5 is an enlarged cross sectional view of the vicinity of the groove 214 in FIG. 4. In the light-emitting element 2 of the present embodiment, a fourth organic layer 208, a second light-emitting layer 209a, and a fifth organic layer 210 are formed between the charge generation layer 207 and the upper electrode 211 in the inside of the groove 214.

The fourth organic layer 208, the second light-emitting layer 209a, and the fifth organic layer 210 are formed in the inside of the groove 214, thereby suppressing thinning of the thickness (“a” in the drawing) of the organic layer between the charge generation layer 207 and the upper electrode 211 at the sidewall portion in the inside of the groove 214. That is, according to the light-emitting element 2 of the present embodiment, the thickness of the organic layer between the charge generation layer 207 and the upper electrode 211 can be made larger than the thickness of the organic layer in the light-emitting element 5 in the prior art.

From the description up to this point, according to the light-emitting element 2, the thickness of the organic layer between the charge generation layer 207 and the upper electrode 211 at the sidewall portion in the inside of the groove 214 is suppressed from becoming thin, and the leakage current between the charge generation layer 207 and the upper electrode 211 is suppressed.

### Third Embodiment

Next, a light-emitting element of a third embodiment will be described. Incidentally, in the following description, the same configurations as those of the foregoing embodiments are given the same reference numerals and signs, and detailed description thereof will be omitted.

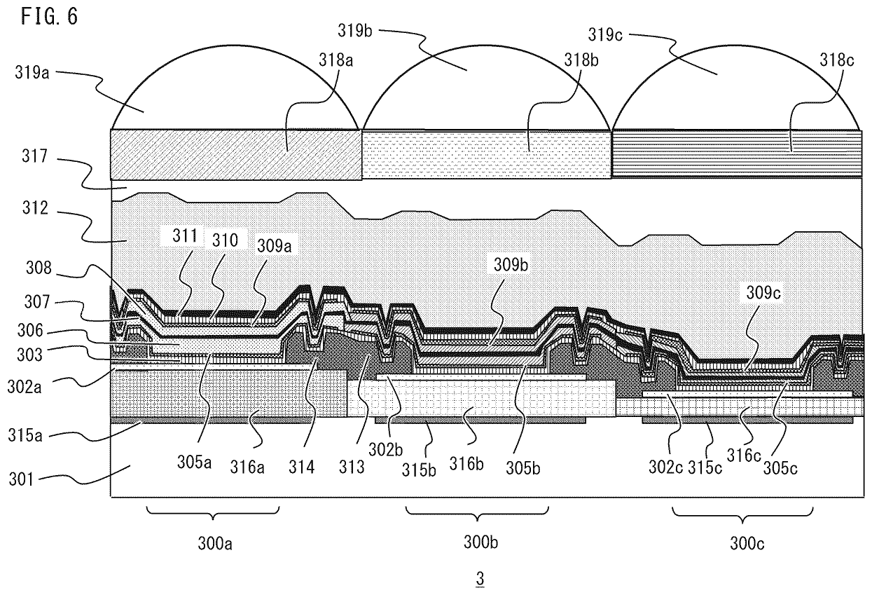

FIG. 6 is a cross sectional view showing an example of a first sub-pixel 300a, a second sub-pixel 300b, and a third sub-pixel 300c of a light-emitting element 3 according to the present embodiment. As shown in the drawing, the light-emitting element 3, as with the light-emitting element 2, has a substrate 301, lower electrodes 302a to 302c, a first organic layer 303, and first light-emitting layers 305a to 305c. Further, the light-emitting element 3 has a third organic layer 306, a charge generation layer 307, a fourth organic layer 308, second light-emitting layers 309a to 309c, a fifth organic layer 310, an upper electrode 311, a protective layer 312, and an insulating layer 313 as with the light-emitting element 2. Furthermore, the light-emitting element 3 has reflection layers 315a to 315c and optical adjustment layers 316a to 316c as with the light-emitting element 2.

In the light-emitting element 3 of the present embodiment, a flattened layer 317 is formed for the light-emitting element 2 of the second embodiment, and color filters 318a to 318c corresponding to the sub-pixels 300a to 300c, respectively, are arranged on the flattened layer 317. The color filters 318a, 318b, and 318c are color filters that transmit different colors, respectively. Incidentally, the light-emitting element 3 may not be provided with the color filters 318a, 318b, and 318c.

Further, on the color filters 318a, 318b, and 318c, microlenses 319a to 319c corresponding to the sub-pixels 300a to 300c, respectively, are formed. Accordingly, according to the light-emitting element 3 of the present embodiment, while suppressing the leakage current between the charge generation layer 307 and the upper electrode 311, the light of each color outputted from the sub-pixels 300a to 300c can be efficiently extracted by the microlenses 319a to 319c.

[Structure of an Organic Light-Emitting Element] In the present embodiment the organic light-emitting element is provided by forming an insulating layer, a first electrode, an organic compound layer and a second electrode, on a substrate. A protective layer, a color filter, a microlens and so forth may be provided on a cathode. In a case where a color filter is provided, a planarization layer may be provided between the color filter and the protective layer. The planarization layer can be for instance made up of an acrylic resin. The same is true in a case where the planarization layer is provided between the color filter and the microlens.

[Substrate] At least one material selected from quartz, glass, silicon, resins and metals can be used as the material for the substrate that makes up the organic light-emitting element. Switching elements such as transistors and wiring may be provided on the substrate, and an insulating layer may be provided on the foregoing. Any material can be used as the insulating layer so long as a contact hole can be formed between the insulating layer and the first electrode, and insulation from unconnected wiring can be ensured, so that wiring can be formed between the first electrode and the insulating layer. For instance a resin such as a polyimide, or silicon oxide or silicon nitride can be used herein.

[Electrodes] A pair of electrodes can be used as the electrodes of the organic light-emitting element. The pair of electrodes may be an anode and a cathode. In a case where an electric field is applied in the direction in which the organic light-emitting element emits light, the electrode of higher potential is the anode, and the other electrode is the cathode. Stated otherwise, the electrode that supplies holes to the light-emitting layer is the anode, and the electrode that supplies electrons is the cathode.

A material having a work function as large as possible is preferable herein as a constituent material of the anode. For instance single metals such as gold, platinum, silver, copper, nickel, palladium, cobalt, selenium, vanadium or tungsten, and mixtures containing the foregoing metals, can be used in the anode. Alternatively, alloys obtained by combining these single metals, or metal oxides such as tin oxide, zinc oxide, indium oxide, indium tin oxide (ITO) or indium zinc oxide, may be used in the anode. Conductive polymers such as polyaniline, polypyrrole and polythiophene can also be used in the anode.

Any of the foregoing electrode materials may be used singly; alternatively, two or more materials may be used concomitantly. The anode may be made up of a single layer, or may be made up of a plurality of layers.

In a case where an electrode of the organic light-emitting element is configured in the form of a reflective electrode, the electrode material can be for instance chromium, aluminum, silver, titanium, tungsten, molybdenum, or alloys or layered bodies of the foregoing. The above materials can also function as a reflective film not having a role as an electrode. In a case where an electrode of the organic light-emitting element is configured in the form of a transparent electrode, for instance an oxide transparent conductive layer of for instance indium tin oxide (ITO) or indium zinc oxide can be used, although not particularly limited thereto, as the electrode material. The electrodes may be formed by photolithography.

A material having a small work function may be a constituent material of the cathode. For instance alkali metals such as lithium, alkaline earth metals such as calcium, single metals such as aluminum, titanium, manganese, silver, lead or chromium, and mixtures of the foregoing, may be used herein. Alternatively, alloys obtained by combining these single metals can also be used. For instance magnesium-silver, aluminum-lithium, aluminum-magnesium, silver-copper or zinc-silver can be used. Metal oxides such as indium tin oxide (ITO) can also be used. These electrode materials may be used singly as one type, or two or more types can be used concomitantly. Also, the cathode may have a single-layer structure or a multilayer structure. Silver is preferably used among the foregoing, and more preferably a silver alloy, in order to reduce silver aggregation. Any alloy ratio can be adopted, so long as silver aggregation can be reduced. A ratio silver:other metal may be for instance 1:1, or 3:1.

Although not particularly limited thereto, the cathode may be a top emission element that utilizes an oxide conductive layer of ITO or the like, or may be a bottom emission element that utilizes a reflective electrode of aluminum (Al) or the like. The method for forming the cathode is not particularly limited, but more preferably for instance a DC or AC sputtering method is resorted to, since in that case film coverage is good and resistance can be readily lowered.

[Pixel Separation Layer] The pixel separation layer of the organic light-emitting element is formed out of a silicon nitride (SiN) film, a silicon oxynitride (SiON) film, or a silicon oxide (SiO) film, in turn having been formed by chemical vapor deposition (CVD). In order to increase the in-plane resistance of the organic compound layer, preferably the thickness of the organic compound layer that is formed, particularly a hole transport layer, is set to be small at the side walls of the pixel separation layer. Specifically, the side walls can be formed to be thin by increasing vignetting at the time of deposition, through an increase of the taper angle of the side walls of the pixel separation layer and/or an increase of the thickness of the pixel separation layer.

On the other hand, it is preferable to adjust the side wall taper angle of the pixel separation layer and the thickness of the pixel separation layer so that no voids are formed in the protective layer that is formed on the pixel separation layer. The occurrence of defects in the protective layer can be reduced by virtue of the fact that no voids are formed in the protective layer. Since the occurrence of defects in the protective layer is thus reduced, it becomes possible to reduce loss of reliability for instance in terms of the occurrence of dark spots or defective conduction in the second electrode.

The present embodiment allows effectively suppressing leakage of charge to adjacent pixels even when the taper angle of the side walls of the pixel separation layer is not sharp. Studies by the inventors of the present application have revealed that leakage of charge to adjacent pixels can be sufficiently reduced if the taper angle lies in the range at least 60 degrees and not more than 90 degrees. The thickness of the pixel separation layer is preferably at least 10 nm and not more than 150 nm. A similar effect can be achieved also in a configuration having only a pixel electrode lacking a pixel separation layer. In this case, however, it is preferable to set the film thickness of the pixel electrode to be half or less the thickness the organic layer, or to impart forward taper at the ends of the pixel electrode, at a taper angle smaller than 60 degrees, since short circuits of the organic light-emitting element can be reduced thereby.

[Organic Compound Layer] The organic compound layer of the organic light-emitting element may be formed out of a single layer or multiple layers. In a case where the organic compound layer has multiple layers, these may be referred to as a hole injection layer, a hole transport layer, an electron blocking layer, a light-emitting layer, a hole blocking layer, an electron transport layer or an electron injection layer, depending on the function of the layer. The organic compound layer is mainly made up of organic compounds, but may contain inorganic atoms and inorganic compounds. For instance the organic compound layer may have copper, lithium, magnesium, aluminum, iridium, platinum, molybdenum or zinc. The organic compound layer may be disposed between the first electrode and the second electrode, and may be disposed in contact with the first electrode and the second electrode.

[Protective Layer] In the organic light-emitting element of the present embodiment, a protective layer may be provided on the second electrode. For instance, intrusion of water or the like into the organic compound layer can be reduced, and the occurrence of display defects also reduced, by bonding a glass provided with a moisture absorbent onto the second electrode. As another embodiment, a passivation film of for instance silicon nitride may be provided on the cathode, to reduce intrusion of water or the like into the organic compound layer. For instance, formation of the cathode may be followed by conveyance to another chamber, without breaking vacuum, whereupon a protective layer may be formed through formation of a silicon nitride film having a thickness of 2 μm by CVD. The protective layer may be provided by atomic deposition (ALD), after film formation by CVD. The material of the film formed by ALD is not limited, but may be for instance silicon nitride, silicon oxide or aluminum oxide. Silicon nitride may be further formed, by CVD, on the film having been formed by ALD. The film formed by ALD may be thinner than the film formed by CVD. Specifically, the thickness of the film formed by ALD may be 50% or less, or 10% or less.

[Color Filter] A color filter may be provided on the protective layer of the organic light-emitting element of the present embodiment. For instance a color filter having factored therein the size of the organic light-emitting element may be provided on another substrate, followed by affixing to a substrate having the organic light-emitting element provided thereon; alternatively, a color filter may be patterned by photolithography on the protective layer illustrated above. The color filter may be made up of a polymer.

[Planarization Layer] The organic light-emitting element of the present embodiment may have a planarization layer between the color filter and the protective layer. The planarization layer is provided for the purpose of reducing underlying layer unevenness. The planarization layer may be referred to as a resin layer in a case where the purpose of the planarization layer is not limited. The planarization layer may be made up of an organic compound, which may be a low-molecular or high-molecular compound, preferably a high-molecular compound.

The planarization layer may be provided above and below the color filter, and the constituent materials of the respective planarization layers may be identical or dissimilar. Concrete examples include polyvinylcarbazole resins, polycarbonate resins, polyester resins, ABS resins, acrylic resins, polyimide resins, phenolic resins, epoxy resins, silicone resins and urea resins.

[Microlens] The organic light-emitting element may have an optical member such as a microlens, on the light exit side. The microlens may be made up of for instance an acrylic resin or an epoxy resin. The purpose of the microlens may be to increase the amount of light extracted from the organic light-emitting element, and to control the direction of the extracted light. The microlens may have a hemispherical shape. In a case where the microlens has a hemispherical shape, then from among tangent lines that are in contact with the hemisphere there is a tangent line that is parallel to the insulating layer, such that the point of contact between that tangent line and the hemisphere is the apex of the microlens. The apex of the microlens can be established similarly in any cross section. That is, among tangent lines that are in contact with a semicircle of the microlens in a sectional view, there is a tangent line that is parallel to the insulating layer, such that the point of contact between that tangent line and the semicircle is the apex of the microlens.

A midpoint of the microlens can also be defined. Given a hypothetical line segment from the end point of an arc shape to the end point of another arc shape, in a cross section of the microlens, the midpoint of that line segment can be referred to as the midpoint of the microlens. The cross section for discriminating the apex and the midpoint may be a cross section that is perpendicular to the insulating layer.

The microlens has a first surface with a convex portion and a second surface on the reverse side from that of the first surface. Preferably, the second surface is disposed closer to a functional layer than the first surface. In adopting such a configuration, the microlens must be formed the organic light-emitting element. In a case where the functional layer is an organic layer, it is preferable to avoid high-temperature processes in the manufacturing process. If a configuration is adopted in which the second surface is disposed closer to the functional layer than the first surface, the glass transition temperatures of all the organic compounds that make up the organic layer are preferably 100° C. or higher, and more preferably 130° C. or higher.

[Counter Substrate] The organic light-emitting element of the present embodiment may have a counter substrate on the planarization layer. The counter substrate is so called because it is provided at a position corresponding to the above-described substrate. The constituent material of the counter substrate may be the same as that of the substrate described above. The counter substrate can be used as the second substrate in a case where the substrate described above is used as the first substrate.

[Organic Layer] Each organic compound layer (hole injection layer, hole transport layer, electron blocking layer, light-emitting layer, hole blocking layer, electron transport layer, electron injection layer and so forth) that makes up the organic light-emitting element of the present embodiment is formed in accordance with one of the methods illustrated below.

A dry process such as vacuum deposition, ionization deposition, sputtering, plasma or the like can be used for the organic compound layers that make up the organic light-emitting element of the present embodiment. A wet process in which a layer is formed through dissolution in an appropriate solvent, relying on a known coating method (for instance spin coating, dipping, casting, LB film deposition to inkjet.) can resorted to instead of a dry process.

When a layer is formed for instance by vacuum deposition or by solution coating, crystallization or the like is unlikelier occur; this translates into superior stability over time. In a case where a film is formed in accordance with a coating method, the film can be formed by being combined with an appropriate binder resin.

Examples of binder resins include, although not limited to, polyvinylcarbazole resins, polycarbonate resins, polyester resins, ABS resins, acrylic resins, polyimide resins, phenolic resins, epoxy resins, silicone resins and urea resins. These binder resins may be used singly as one type, in the form of homopolymers or copolymers; alternatively, two or more types of binder resin may be used in the form of mixtures. Additives such as known plasticizers, antioxidants and ultraviolet absorbers may be further used concomitantly, as needed.

[Pixel Circuit] A light-emitting device having the organic light-emitting element of the present embodiment may have pixel circuits connected to respective organic light-emitting elements. The pixel circuits may be of active matrix type, and may control independently emission of light by the first organic light-emitting element and the second organic light-emitting element. Active matrix circuits may be voltage-programmed or current-programmed. A drive circuit has a pixel circuit for each pixel. Each pixel circuit may have an organic light-emitting element, a transistor that controls the emission luminance of the organic light-emitting element, a transistor that controls emission timing, a capacitor which holds the gate voltage of the transistor that controls emission luminance, and a transistor for connection to GND bypassing the light-emitting element.

The light-emitting device has a display area and a peripheral area disposed around the display area. The display area has pixel circuits, and the peripheral area has a display control circuit. The mobility of the transistors that make up the pixel circuits may be lower than the mobility of the transistors that make up the display control circuit. The slope of the current-voltage characteristic of the transistors that make up the pixel circuits may be gentler than the slope of the current-voltage characteristic of the transistors that make up the display control circuit. The slope of the current-voltage characteristics can be measured on the basis of a so-called Vg-Ig characteristic. The transistors that make up the pixel circuits are connected to light-emitting elements such as the first organic light-emitting element.

[Pixels] The organic light-emitting element of the present embodiment has a plurality of pixels. The pixels have sub-pixels that emit mutually different colors. The sub-pixels may have for instance respective RGB emission colors. The pixels emit light in a pixel opening region. This region is the same as the first region. The aperture diameter of the pixel openings may be 15 μm or smaller, and may be 5 μm or larger. More specifically, the aperture diameter of the pixel openings may be for instance 11 μm, or 9.5 μm, or 7.4 μm, or 6.4 μm. The spacing between sub-pixels may be 10 μm or smaller, specifically 8 μm, or 7.4 μm, or 6.4 μm.

The pixels can have any known arrangement in a plan view. For instance, the pixel layout may be a stripe arrangement, a delta arrangement, a penile arrangement or a Bayer arrangement. The shape of the sub-pixels in a plan view may be any known shape. For instance, the sub-pixel shape may be for instance quadrangular, such as rectangular or rhomboidal, or may be hexagonal. Needless to say, the shape of the sub-pixels is not an exact shape, and a shape close to that a of rectangle falls under a rectangular shape. Sub-pixel shapes and pixel arrays can be combined with each other.

[Use of the Organic Light-Emitting Element] The organic light-emitting element according to the present embodiment can be used as a constituent member of a display device or of a lighting device. Other uses of the organic light-emitting element include exposure light sources for electrophotographic image forming apparatuses, backlights for liquid crystal display devices, and light-emitting devices having color filters, in white light sources.

The display device may be an image information processing device having an image input unit for input of image information, for instance from an area CCD, a linear CCD or a memory card, and an information processing unit for processing inputted information, such that an inputted image is displayed on a display unit.

A display unit of an imaging device or of an inkjet printer may have a touch panel function. The driving scheme of this touch panel function may be an infrared scheme, a capacitive scheme, a resistive film scheme or an electromagnetic induction scheme, and is not particularly limited. The display device may also be used in a display unit of a multi-function printer.

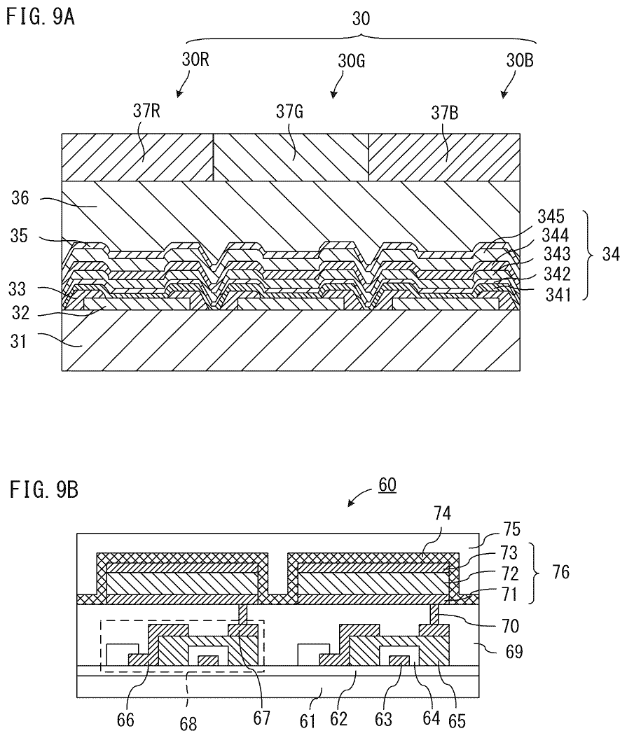

A display device provided with the organic light-emitting element according to the present embodiment will be explained next with reference to accompanying drawings. FIG. 9A and FIG. 9B are cross-sectional schematic diagrams illustrating examples of a display device having organic light-emitting elements and transistors connected to respective organic light-emitting elements. The transistors are an example of active elements. The transistors may be thin-film transistors (TFTs).

FIG. 9A is an example of a pixel, which is a constituent element of a display device having the organic light-emitting element according to the present embodiment. The pixel has sub-pixels 30. The sub-pixels 30 are divided into 30R, 30G and 30B, depending on the respective emission light of the sub-pixel. The emission color may be made different on the basis of the wavelength emitted from the light-emitting layer; alternatively, the light emitted from each sub-pixel may be selectively transmitted or color-converted for instance by a respective color filter. Each sub-pixel has a reflective electrode 32 as a first electrode on an interlayer insulating layer 31, and an insulating layer 33 that covers the edge of the reflective electrode 32. Each sub-pixel has an organic compound layer 34 that covers the reflective electrode 32 and the insulating layer 33, a transparent electrode 35 as a second electrode, a protective layer 36, and a respective color filter 37R, 37G or 37B.

The interlayer insulating layer 31 may have transistors and capacitive elements disposed thereunder or in the interior. The transistors and the first electrode may be electrically connected for instance by way of contact holes (not shown).

The insulating layer 33 is also referred to as a bank or as pixel separation film. The insulating layer 33 is disposed covering the edge of the first electrode while surrounding the first electrode. Portions where the insulating layer is not disposed are in contact with the organic compound layer 34, yielding emission regions. The organic compound layer 34 has a hole injection layer 341, a hole transport layer 342, a first light-emitting layer 343, a second light-emitting layer 344 and an electron transport layer 345.

The transparent electrode 35, as the second electrode, may be a transparent electrode, a reflective electrode, or a semi-transparent electrode. The protective layer 36 reduces permeation of moisture into the organic compound layer. The protective layer 36 is illustrated herein in the form of one layer, but may be multiple layers. Each protective layer 36 may have an inorganic compound layer or an organic compound layer. The color filters are divided into a color filter 37R, a color filter 37G and a color filter 37B, according to the color thereof. The color filters may be formed on a planarization film, not shown. A resin protective layer, not shown, may be provided on the color filters. The color filters may be formed on the protective layer 36. Alternatively, the color filters may be affixed after having been provided on a counter substrate such as a glass substrate.

FIG. 9B illustrates a display device 60 having the organic light-emitting element of the present embodiment. The display device 60 has organic light-emitting elements 76 and TFTs 68 as an example of a transistor. The display device 60 is provided with a substrate 61 made up of glass, silicon or the like, and an insulating layer 62 at the top of the substrate 61. Respective active elements such as TFTs 68 are disposed on the insulating layer, such that a gate electrode 63, a gate insulating film 64 and a semiconductor layer 65 of each active element are disposed therein. Each TFT 68 is also made up of the semiconductor layer 65, a drain electrode 66 and a source electrode 67. An insulating film 69 is provided on the TFTs 68. An anode 71 and a source electrode 67 that make up a respective organic light-emitting element 76 are connected through a contact hole 70 provided in the insulating film 69.

The method for electrically connecting the electrodes (anode and cathode) included in each organic light-emitting element 76 and the electrodes (source electrode and drain electrode) included in the respective TFT 68 is not limited to the implementation illustrated in FIG. 9B. Specifically, it suffices that either one from among the anode and the cathode be electrically connected to either a TFT source electrode or a TFT drain electrode. The acronym TFT signifies thin-film transistor.

In the display device 60 of FIG. 9B, the organic compound layer is illustrated as one layer, but the organic compound layer 72 may be a plurality of layers. A first protective layer 74 and a second protective layer 75 for reducing deterioration of the organic light-emitting element are provided on the cathode 73.

Although transistors are used as switching elements in the display device 60 of FIG. 9B, other switching elements may be used instead. The transistors used in the display device 60 of FIG. 9B are not limited to transistors that utilize a single-crystal silicon wafer, and may be thin-film transistors having an active layer on an insulating surface of a substrate. Examples of active layers include single-crystal silicon, non-single-crystal silicon such an amorphous silicon or microcrystalline silicon, as well as non-single-crystal oxide semiconductors such as indium zinc oxide or indium gallium zinc oxide. Thin-film transistors are also referred to as TFT elements.

The transistors included in the display device 60 of FIG. 9B may be formed in a substrate such as a Si substrate. The wording “formed in a substrate” signifies that transistors are produced by processing the substrate itself, for instance a Si substrate. That is, the feature of having transistors in the substrate may signify that the substrate and the transistors are integrally formed with each other.

The emission luminance of the organic light-emitting element according to the present embodiment is controlled by a TFT, which is an example of a switching element; an image can be thus displayed according to respective values of emission luminance, by providing a plurality of organic light-emitting elements within a plane. The switching element according to the present embodiment is not limited to a TFT, and may be a transistor made up of low-temperature polysilicon, or an active matrix driver formed on a substrate such as a Si substrate. The wording “on the substrate” can also signify herein “in the substrate”. The size of the display unit governs the choice of whether the transistors are to be provided in the substrate, or whether TFTs are to be used; if for instance the size of the display unit is about 0.5 inches, it is preferable to provide the organic light-emitting elements on a Si substrate.

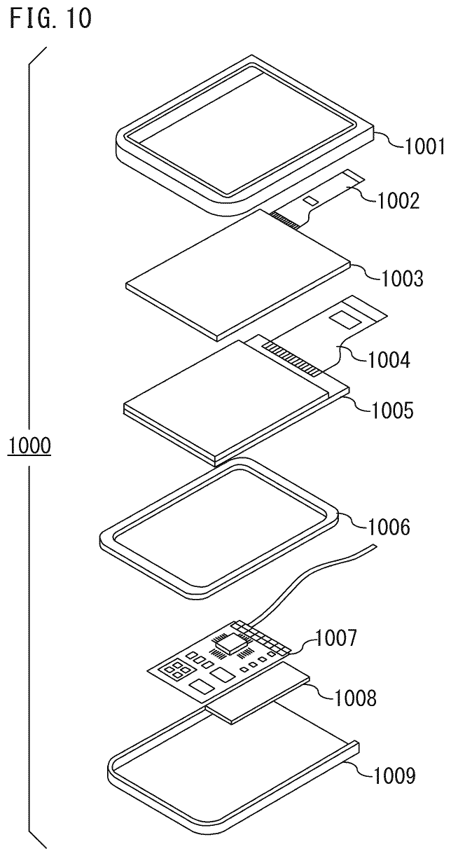

Next, FIG. 10 illustrates a schematic diagram depicting an example of a display device having an organic light-emitting element according to the present embodiment. A display device 1000 may have a touch panel 1003, a display panel 1005, a frame 1006, a circuit board 1007 and a battery 1008, between an upper cover 1001 and a lower cover 1009. The touch panel 1003 and the display panel 1005 are connected to flexible printed circuits FPCs 1002, 1004. Transistors are printed on the circuit board 1007. The battery 1008 may be omitted if the display device is not a portable device; even if the display device is a portable device, the battery 1008 may be provided at a different position.

The display device 1000 may have red, green and blue color filters. The color filters may be disposed in a delta arrangement of the above red, green and blue. The display device 1000 may be used as a display unit of a mobile terminal. In that case the display device 1000 may have both a display function and an operation function. Mobile terminals include mobile phones such as smartphones, tablets and head-mounted displays.

The display device 1000 may be used in a display unit of an imaging device that has an optical unit having a plurality of lenses, and that has an imaging element which receives light having passed through the optical unit. The imaging device may have a display unit that displays information acquired by the imaging element. The display unit may be a display unit exposed outside the imaging device, or may be a display unit disposed within a viewfinder. The imaging device may be a digital camera or a digital video camera.

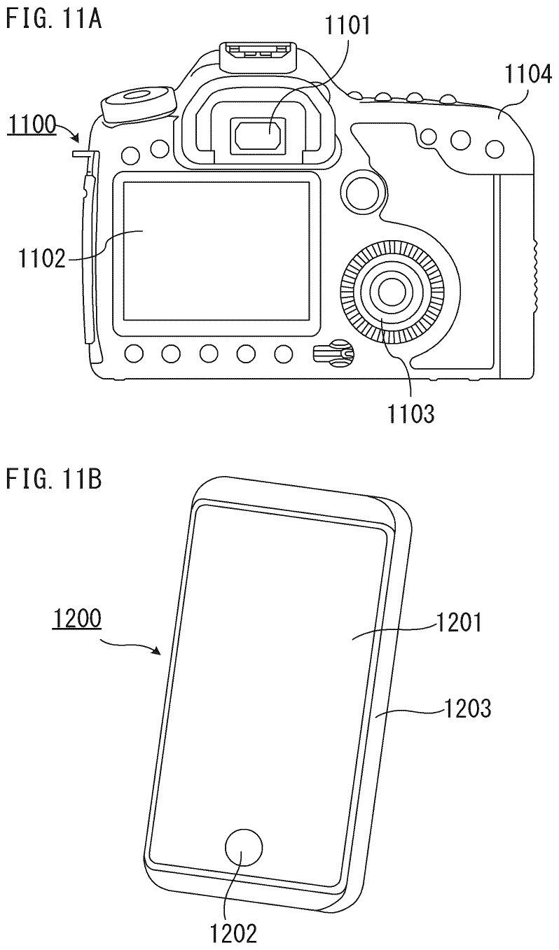

Next, FIG. 11A illustrates a schematic diagram depicting an example of an imaging device having the organic light-emitting element according to the present embodiment. An imaging device 1100 may have a viewfinder 1101, a rear display 1102, an operation unit 1103 and a housing 1104. The viewfinder 1101 may have the display device according to the present embodiment. In that case the display device may display not only an image to be captured, but also for instance environment information and imaging instructions. The environment information may include for instance external light intensity, external light orientation, the moving speed of a subject, and the chance of the subject being blocked by an obstacle.

The timing suitable for imaging is short, and hence information should be displayed as soon as possible. It is therefore preferable to configure the display device so as to have high response speed, using the organic light-emitting element of the present embodiment. A display device that utilizes the organic light-emitting element can be utilized more suitably than these devices or liquid crystal display devices, where high display speed is required.

The imaging device 1100 has an optical unit, not shown. The optical unit has a plurality of lenses, and forms an image on an imaging element accommodated in the housing 1104. The lenses can be focused through adjustment of the relative positions thereof. This operation can also be performed automatically. The imaging device may be referred to as a photoelectric conversion device. The photoelectric conversion device can encompass, as an imaging method other than sequential imaging, a method that involves detecting a difference relative to a previous image, and a method that involves cutting out part of a recorded image.

FIG. 11B is a schematic diagram illustrating an example of an electronic device having the organic light-emitting element according to the present embodiment. An electronic device 1200 includes a display unit 1201, an operation unit 1202, and a housing 1203. The housing 1203 may have a circuit, a printed board having the circuit, a battery, and a communication unit. The operation unit 1202 may be a button, or a touch panel-type reaction unit. The operation unit may be a biometric recognition unit which for instance performs unlocking upon recognition of a fingerprint. The electronic device having a communication unit can also be referred to as a communication device. The electronic device 1200 may further have a camera function, by being provided with a lens and an imaging element. Images captured by way of the camera function are displayed on the display unit. Examples of the electronic device include smartphones and notebook computers.

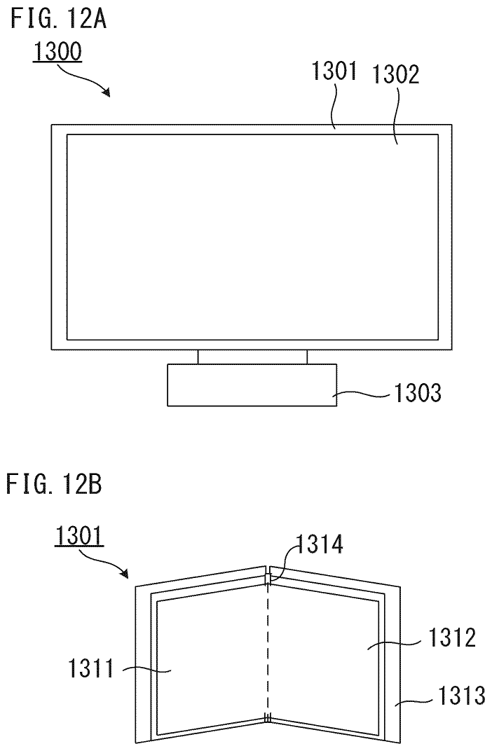

Next, FIG. 12A illustrates a schematic diagram depicting an example of a display device having the organic light-emitting element according to the present embodiment. FIG. 12A illustrates a display device 1300 such as a television monitor or PC monitor. The display device 1300 has a frame 1301 and a display unit 1302. The display unit 1302 may use the organic light-emitting element according to the present embodiment. The display device 1300 also has the frame 1301 and a base 1303 that supports the display unit 1302. The form of the base 1303 is not limited to the form in FIG. 12A. The lower side of the frame 1301 may also double as the base. The frame 1301 and the display unit 1302 may be curved. The radius of curvature of the foregoing may be at least 5000 mm and not more than 6000 mm.

FIG. 12B is a schematic diagram illustrating another example of a display device having the organic light-emitting element according to the present embodiment. A display device 1310 in FIG. 12B is a so-called foldable display device, configured to be foldable. The display device 1310 has a first display unit 1311, a second display unit 1312, a housing 1313 and a folding point 1314. The first display unit 1311 and the second display unit 1312 may have the organic light-emitting element according to the present embodiment. The first display unit 1311 and the second display unit 1312 may be one seamless display device. The first display unit 1311 and the second display unit 1312 can be separated at the folding point. The first display unit 1311 and the second display unit 1312 may display different images; alternatively, the first display unit and the second display unit may display one image.

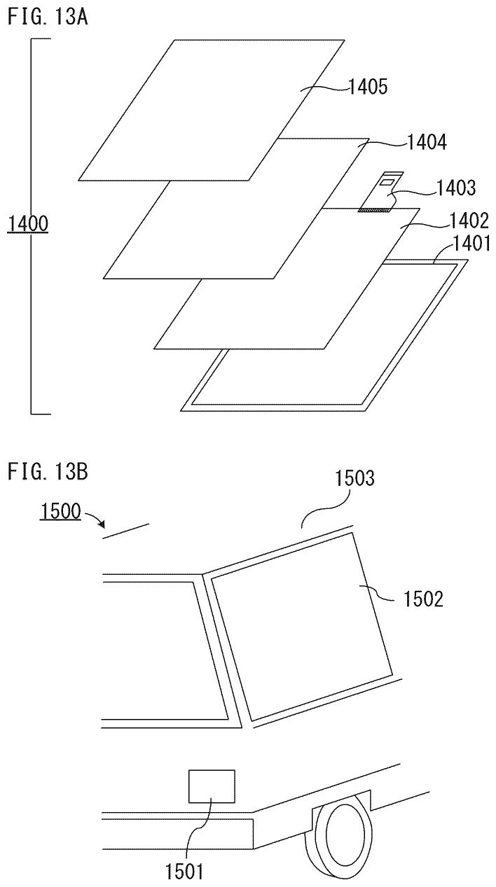

FIG. 13A illustrates next a schematic diagram depicting an example of a lighting device having the organic light-emitting element according to the present embodiment. A lighting device 1400 may have a housing 1401, a light source 1402, a circuit board 1403, an optical film 1404 and a light-diffusing part 1405. The light source has the organic light-emitting element according to the present embodiment. The optical film may be a filter that enhances the color rendering of the light source. The light-diffusing part allows effectively diffusing light from the light source, and allows delivering light over a wide area, for instance in exterior decorative lighting. The optical filter and the light-diffusing part may be provided on the light exit side of the lighting device. A cover may be provided on the outermost part, as the case may require.

The lighting device 1400 is for instance a device for indoor illumination. The lighting device may emit white, daylight white, or other colors from blue to red. The lighting device may have a light control circuit for controlling light having the foregoing emission colors. The lighting device 1400 may have the organic light-emitting element according to the present embodiment, and a power supply circuit connected thereto. The power supply circuit is a circuit that converts AC voltage to DC voltage. White denotes herein a color with a color temperature of 4200 K, and daylight white denotes a color with a color temperature of 5000 K. The lighting device 1400 may have a color filter. The lighting device 1400 may have a heat dissipation part. The heat dissipation part dumps, out of the device, heat from inside the device; the heat dissipation part may be made up of a metal or of liquid silicone rubber, exhibiting high specific heat.

FIG. 13B is a schematic diagram of an automobile, which is an example of a moving body having the organic light-emitting element according to the present embodiment. The automobile has tail lamps, being an example of a lamp. The automobile 1500 may have a tail lamp 1501, of a form such that the tail lamp is lit up when for instance a braking operation is performed.

The tail lamp 1501 has the organic light-emitting element according to the present embodiment. The tail lamp may have a protective member that protects the organic light-emitting element. The protective member may be made up of any material, so long as the material has a certain degree of high strength and is transparent; the protective member is preferably made up of polycarbonate or the like. For instance a furandicarboxylic acid derivative or an acrylonitrile derivative may be mixed with the polycarbonate.

The automobile 1500 may have a vehicle body 1503, and a window 1502 attached to the vehicle body 1503. The window may be a transparent display, unless the purpose of the window is to look ahead and behind the automobile. The transparent display may have the organic light-emitting element according to the present embodiment. In that case, constituent materials such as the electrodes of the organic light-emitting element are made up of transparent members.

The moving body having the organic light-emitting element according to the present embodiment may be for instance a vessel, an aircraft or a drone. The moving body may have a body frame and a lamp provided on the body frame. The lamp may emit light for indicating the position of the body frame. The lamp has the organic light-emitting element according to the present embodiment.

Also, the display device having the organic light-emitting element of the present embodiment can be used in a system that can be worn as a wearable device, such as smart glasses, HMDs or smart contacts. An imaging display device used in such an application example may have an imaging device capable of photoelectrically converting visible light, and a display device capable of emitting visible light.

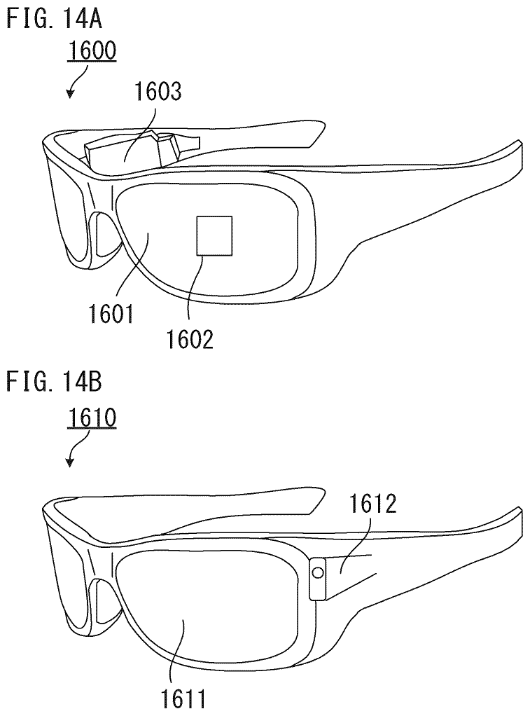

FIG. 14A illustrates spectacles 1600 (smart glasses) according to an application example of the display device having the organic light-emitting element of the present embodiment. An imaging device 1602 such as a CMOS sensor or a SPAD is provided on the front surface side of a lens 1601 of the spectacles 1600. A display device of the embodiments described above is provided on the back surface side of the lens 1601.

The spectacles 1600 further have a control device 1603. The control device 1603 functions as a power supply that supplies power to the imaging device 1602 and to the display device according to the embodiments. The control device 1603 controls the operations of the imaging device 1602 and of the display device. The lens 1601 has formed therein an optical system for condensing light onto the imaging device 1602.

FIG. 14B illustrates spectacles 1610 (smart glasses) according to another application example of the display device having the organic light-emitting element of the present embodiment. The spectacles 1610 have a control device 1612. The control device 1612 has mounted therein an imaging device corresponding to the imaging device 1602, and a display device. In a lens 1611 there is formed an optical system for projecting the light emitted by the display device in the control device 1612, such that an image is projected onto the lens 1611. The control device 1612 functions as a power supply that supplies power to the imaging device and to the display device, and controls the operations of the imaging device and of the display device. The control device may have a line-of-sight detection unit that detects the line of sight of the wearer. Infrared rays may be used herein for line-of-sight detection. An infrared light-emitting unit emits infrared light towards one eyeball of a user who is gazing at a display image. The infrared light emitted is reflected by the eyeball, and is detected by an imaging unit having a light-receiving element, whereby a captured image of the eyeball is obtained as a result. Impairment of the appearance of the image is reduced herein by having a reducing means for reducing light from the infrared light-emitting unit to the display unit, in a plan view.

The line of sight of the user with respect to the display image is detected on the basis of the captured image of the eyeball obtained through infrared light capture. Any known method can be adopted for line-of-sight detection using the captured image of the eyeball. As an example, a line-of-sight detection method can be resorted to that utilizes Purkinje images obtained through reflection of irradiation light on the cornea. More specifically, line-of-sight detection processing based on a pupillary-corneal reflection method is carried out herein. The line of sight of the user is detected by calculating a line-of-sight vector that represents the orientation (rotation angle) of the eyeball, on the basis of a Purkinje image and a pupil image included in the captured image of the eyeball, in accordance with a pupillary-corneal reflection method.

The display device having the organic light-emitting element according to the present embodiment may have an imaging device having a light-receiving element, and may control the display image of the display device on the basis of line-of-sight information about the user, from the imaging device.

Specifically, a first visual field area gazed at by the user and a second visual field area, other than the first visual field area, are determined in the display device on the basis of line-of-sight information. The first visual field area and the second visual field area may be determined by the control device of the display device; alternatively, the display device may receive visual field areas determined by an external control device. In a display area of the display device, the display resolution in the first visual field area may be controlled to be higher than the display resolution in the second visual field area. That is, the resolution in the second visual field area may set to be lower than that of the first visual field area.

The display area may have a first display area and a second display area different from the first display area, such that the display device selects the area of higher priority, from among the first display area and the second display area, on the basis of the line-of-sight information. The first display area and the second display area may be determined by the control device of the display device; alternatively, the display device may receive display areas determined by an external control device. The display device may control the resolution in a high-priority area so as to be higher than the resolution in areas other than high-priority areas. That is, the display device may lower the resolution in areas of relatively low priority.

Herein AI (Artificial Intelligence) may be used to determine the first visual field area and high-priority areas. The AI may be a model constructed to estimate, from an image of the eyeball, a line-of-sight angle, and the distance to an object lying ahead in the line of sight, using training data in the form of the image of the eyeball and the direction towards which the eyeball in the image was actually gazing at. An AI program may be provided in the display device, in the imaging device, or in an external device. In a case where an external device has the AI program, the AI program is transmitted to the display device via communication from the external device.

In a case where the display device performs display control on the basis of on visual recognition detection, the display device can be preferably used in smart glasses further having an imaging device that captures images of the exterior. The smart glasses can display captured external information in real time.

According to the technique of the present disclosure, in an organic light-emitting element, a leakage current between a charge generation layer and an upper electrode in a pixel can be suppressed while enhancing the light-emitting efficiency by a microcavity effect.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

What is claimed is:

1. An organic light-emitting element, comprising:
a first element having, on a substrate, a first lower electrode, a first light-emitting layer that emits light of a first color, a charge generation layer, a second light-emitting layer that emits light of the first color, and an upper electrode in this order; and
an insulating layer covering an end of the first lower electrode, wherein
the first element has one or more organic layers between the first lower electrode and the charge generation layer, and has one or more organic layers between the charge generation layer and the upper electrode,
the insulating layer has a groove on a surface that is in contact with the organic layer disposed between the first lower electrode and the charge generation layer, and
at least one of the organic layers disposed between the charge generation layer and the upper electrode is formed in the groove.

2. The organic light-emitting element according to claim 1, wherein the thickest layer of the one or more organic layers disposed between the charge generation layer and the upper electrode is formed in the groove.

3. The organic light-emitting element according to claim 1, wherein the second light-emitting layer is formed in the groove.

4. The organic light-emitting element according to claim 1, wherein
the first element further comprises an electron transport layer between the charge generation layer and the upper electrode, and
the electron transport layer is formed in the groove.

5. The organic light-emitting element according to claim 1, wherein at least one organic layer of the one or more organic layers disposed between the first lower electrode and the charge generation layer is not formed in the groove.

6. The organic light-emitting element according to claim 1, wherein
the first element comprises one or more organic layers between the first lower electrode and the charge generation layer, and
at least one organic layer of the one or more organic layers disposed between the first lower electrode and the charge generation layer is not formed in the groove.

7. The organic light-emitting element according to claim 1, further comprising a second element having, on the substrate, a second lower electrode, a third light-emitting layer that emits light of a second color different from the first color, the charge generation layer, a fourth light-emitting layer that emits light of the second color, and the upper electrode in this order, wherein
the second lower electrode is adjacent to the first lower electrode, and
the second element has one or more organic layers between the charge generation layer and the upper electrode.

8. The organic light-emitting element according to claim 7, wherein the fourth light-emitting layer is formed in the groove.

9. The organic light-emitting element according to claim 7, wherein
the second element comprises one or more organic layers between the second lower electrode and the charge generation layer, and
at least one organic layer of the one or more organic layers disposed between the second lower electrode and the charge generation layer is not formed in the groove.

10. The organic light-emitting element according to claim 7, wherein
the first element has a reflective layer and a first optical adjustment layer, and
the second element has the reflective layer and a second optical adjustment layer.

11. The organic light-emitting element according to claim 1, further comprising a lens on a light exit side of the organic light-emitting element.

12. A display device comprising a plurality of pixels, wherein
at least one of the plurality of pixels comprises the organic light-emitting element according to claim 1, and a transistor connected to the organic light-emitting element.

13. A photoelectric conversion device, comprising:
an optical unit having a plurality of lenses;
an imaging element for receiving light that has passed through the optical unit; and
a display unit that displays an image captured by the imaging element, wherein
the display unit has the organic light-emitting element according to claim 1.

14. An electronic apparatus, comprising:
a display unit having the organic light-emitting element according to claim 1;
a housing provided with the display unit; and
a communication unit provided in the housing and for communicating with the outside.

15. A lighting device comprising:
a light source having the organic light-emitting element according to claim 1; and
a light diffusion part or an optical film that transmits light emitted by the light source.

16. A moving body comprising:
a lamp having the organic light-emitting element according to claim 1; and
a body provided with the lamp.
